(19) United States
(12) Patent Application Publication
(10) Pub. No.: US 2024/0389267 A1
(43) Pub. Date: Nov. 21, 2024

(54) COOLING APPARATUS AND ELECTRONIC DEVICE

(71) Applicant: BITMAIN TECHNOLOGIES INC., Beijing (CN)

(72) Inventors: Ketuan ZHAN, Beijing (CN); Hongbo ZENG, Beijing (CN); Yang LI, Beijing (CN); Cheng LI, Beijing (CN); Hangkong HU, Beijing (CN); Mingliang HAO, Beijing (CN); Te PI, Beijing (CN); Haicai LV, Beijing (CN); Yongbo GE, Beijing (CN)

(21) Appl. No.: 18/667,942

(22) Filed: May 17, 2024

Related U.S. Application Data
(63) Continuation of application No. PCT/CN2022/132233, filed on Nov. 16, 2022.

(30) Foreign Application Priority Data
Nov. 19, 2021 (CN) 202111401958.8

(51) Int. Cl. H05K 7/20; H05K 1/02

(52) U.S. Cl. CPC H05K 7/203; H05K 1/0203; H05K 7/20318; H05K 7/20327; H05K 7/20381

(57) ABSTRACT

A cooling apparatus and an electronic device, where, the cooling apparatus includes: a condensing part and a sealing part, where the sealing part can accommodate a cooling liquid, and a circuit board mounted with a heat-producing element can be immersed in the cooling liquid; and the condensing part includes a condensing tube and an air cooling structure used for dissipating heat of the condensing tube, the condensing tube is connected with the sealing part, and the air cooling structure is provided on at least one side of the condensing tube.

The present disclosure claims priority to Chinese patent application No. 202111401958.8, filed on Nov. 19, 2021, and entitled “Cooling Apparatus and Electronic Device”; which is hereby incorporated by reference in its entirety.

### TECHNICAL FIELD

The present disclosure relates to but is not limited to the field of heat sink technology and, in particular, to a cooling apparatus and an electronic device.

### BACKGROUND

With the increasing power of electronic devices, the heat dissipation problem of key devices has gradually become a technical bottleneck for various manufacturers. The heat dissipation problem directly affects the life and power consumption of electronic devices. At present, conventional consumer electronic devices often use natural heat dissipation or forced air cooling for heat dissipation. Part of data centers have installed water-cooled heat dissipation devices, but due to a large number of heat-producing elements arranged on circuit boards and the continuous increase in heat flux density, the temperature uniformity of electronic elements has become a new issue.

During setting up liquid cooling heat dissipation devices in related technologies, additional external components are usually used, for example, peripherally arranged liquid cooling related devices, such as a condensation ring tube and a pump provided independent of an internal heat dissipation mechanism of a current electronic device. This not only has high design complexity, occupies a large space, but also has large reliability and cost problems.

There is currently no effective solution proposed to address the issue of the design complexity and volume size of solving the heat dissipation problem of electronic devices in related technologies being far greater than the actual application requirements.

### SUMMARY

The present disclosure provides a cooling apparatus and an electronic device to reduce design complexity and save internal space of the electronic device.

According to a first aspect of the present disclosure, there is provided a cooling apparatus, which includes: a condensing part and a sealing part, where, the sealing part can accommodate a cooling liquid, and a circuit board mounted with a heat-producing element can be immersed in the cooling liquid; and the condensing part includes a condensing tube and an air cooling structure used for dissipating heat of the condensing tube, the condensing tube is connected with the sealing part, and the air cooling structure is provided on at least one side of the condensing tube.

According to a second aspect of the present disclosure, there is provided an electronic device, which includes: the cooling apparatus and the circuit board as described above, where the circuit board is immersed in the cooling liquid in the sealing part, a first surface of the circuit board faces toward a liquid surface of the cooling liquid, a number of heat-producing elements provided on the first surface is greater than a number of heat-producing elements provided on a second surface of the circuit board, and the first surface is opposite to the second surface.

In the present disclosure, the cooling liquid that can be used to cool the circuit board during operation is accommodated in the sealing part. After the cooling liquid vaporizes, the cooling liquid is converted from a gaseous state to a liquid state through the condensing part and flows back to the sealing part, achieving heat dissipation of the circuit board in operation through a liquid cooling mode plus an air cooling mode. Thereby, by using phase change heat transfer, the chip operating temperature can be effectively reduced. And without the need for separate design and arrangement of additional liquid cooling structures, design complexity is reduced and internal space of the electronic device is saved.

For the technical solution provided in the present disclosure, it should be understood that the general description above and the detailed description in the following text are only for illustrative and example purposes, and cannot limit the present disclosure.

### BRIEF DESCRIPTION OF DRAWINGS

The accompanying drawings are incorporated into the specification and form a part of the specification, which illustrates embodiments in accordance with the present disclosure and are used to explain the principles of the present disclosure together with the specification.

FIG. 1 shows a schematic diagram of a cooling apparatus provided by an example embodiment.

FIG. 2 shows a schematic diagram of fins of a condensing tube in a cooling apparatus provided by an example embodiment.

FIG. 3 shows a schematic exploded diagram of a cooling apparatus provided by an example embodiment.

FIG. 4 shows a schematic sectional diagram of a cooling apparatus provided by an example embodiment.

FIG. 5 shows a schematic diagram of an electronic device provided by an example embodiment.

FIG. 6 shows a schematic diagram of an appearance of an electronic device provided by an example embodiment.

### DESCRIPTION OF EMBODIMENTS

The following describes the disclosed embodiments in conjunction with the accompanying drawings. In the following description, reference is made to the accompanying drawings that form a part of the present disclosure and illustrate specific aspects of the disclosed embodiments in an explanatory manner or for which specific aspects of the disclosed embodiments can be used. It should be understood that the disclosed embodiments may be used in other aspects and may include structural or logical variations not depicted in the accompanying drawings. Therefore, the following detailed description should not be understood in a restrictive sense. For example, it should be understood that the disclosed content of the described method can also be applied to the corresponding devices or systems used to perform the method, and vice versa. For example, if one or more specific method steps are described, the corresponding device may include one or more units such as functional units to perform the described one or more method steps (e.g., one unit performs one or more steps, or multiple units, each of which performs one or more steps), even if such one or more units are not explicitly described or illustrated in the accompanying drawings. On the other hand, for example, if a specific device is described based on one or more units such as functional units, the corresponding method may include a step to execute the functionality of one or more units (e.g., one step executes the functionality of one or more units, or multiple steps, where each executes the functionality of one or more units in multiple units), even if such one or more steps are not explicitly described or illustrated in the accompanying drawings. Furthermore, it should be understood that unless otherwise explicitly stated, the features of the example embodiments and/or aspects described herein may be combined with each other.

Embodiments of the present disclosure provide a cooling apparatus that can be installed in electronic devices or externally connected to electronic devices, configured to dissipate heat from circuit boards with one or more heat-producing elements installed in the electronic devices. For example, a circuit board can be a computing power board in a computing device, a mainboard in a service cabinet, etc.

FIG. 1 shows a schematic diagram of a cooling apparatus provided by an example embodiment. As shown in FIG. 1, the cooling apparatus may include a condensing part 12 and a sealing part 14. The sealing part 14 can accommodate a cooling liquid, and a circuit board 20 mounted with a heat-producing element can be immersed in the cooling liquid to dissipate heat from the circuit board 20 in an immersing way. The condensing part 12 may include a condensing tube 121 and an air cooling structure 122 used for dissipating heat of the condensing tube, the condensing tube 121 is connected with the sealing part 14, and the air cooling structure 122 is provided on at least one side of the condensing tube 121.

In one example, as shown in FIG. 1, the cooling apparatus provided in the embodiments of the present disclosure is composed of the condensing part 12 and the sealing part 14. The sealing part 14 is used to store the cooling liquid and the circuit board 20. The circuit board 20 is immersed in the cooling liquid. When the elements located in the circuit board 20 generate heat while the circuit board 20 is in operation, the cooling liquid takes away the surface heat of the elements and vaporizes from liquid to gas, so as to reach the condensing tube 121 in the condensing part 12. Based on position relationship of the air cooling structure 122 provided on at least one side of the condensing tube 121, the air cooling structure 122 dissipates heat from the condensing tube 121. The vaporized cooling liquid is converted from gas to liquid in the condensing tube 121 and flows back to the sealing part 14 again.

It should be noted that in the embodiments of the present disclosure, the circuit board 20 can be a Printed Circuit Board 20 Assembly (Printed Circuit Board Assembly, referred to as PCBA). PCBA includes a TOP surface (also known as a front surface, i.e. a first surface) and a BOT surface (also known as a back surface, i.e. a second surface), where the number of heat-producing elements on the TOP surface is greater than that on the BOT surface. In practical applications, the above-mentioned heat-producing elements can be high-power chips such as CPUs and GPUs.

In the embodiments of the present disclosure, after the cooling liquid is injected into the sealing part 14, the PCBA is completely immersed in the cooling liquid, with the TOP surface facing a liquid surface of the cooling liquid, which can also be understood as the TOP surface facing upwards.

In the embodiments of the present disclosure, for the PCBA, a shape of specific parts of the circuit board can change through hollowing process, thereby promoting a rise of bubbles on the back surface of the PCBA. The rise of bubbles on the back surface of the PCBA can also be promoted by controlling a tilt angle of the PCBA. The embodiments of the present disclosure is only described by using the above example, which is subject to the cooling apparatus provided for implementing the embodiments of the present disclosure, and is not limited in detail.

So, after the various components on the PCBA are in operation, as the power of the heat-producing element increases, the heat-producing element on the TOP surface generates heat, causing local boiling of the cooling liquid. The cooling liquid absorbs the heat of the heat-producing element and carries away the heat of the heat-producing element through vaporization (i.e. the cooling liquid changes from liquid to gas), thereby dissipating the heat of the heat-producing element and ensuring the stability of its operating temperature. Then, the cooling liquid in gaseous state rises from the sealing part 14 to the condensing part 12 and enters the condensing tube 121. The air cooling structure 122 dissipates heat from the condensing tube 121, causing a decrease in temperature as it enters the condensing tube 121, so as to condense the gaseous cooling liquid, transform the cooling liquid from a gaseous state to a liquid state, which then flows back to the sealing part 14. In this way, heat dissipation of the circuit board 20 is achieved through a two-phase circulation of the cooling liquid.

In some possible embodiments, the above-mentioned condensing tube 121 may be one or more condensing tubes. When there are multiple condensing tubes 121 in the condensing part 12, the placement of the condensing tubes 121 can be distributed according to the reserved positions of the sealing part 14. The reserved positions can be set according to a position of each heat-producing element on the PCBA, therefore, for each heat-producing element position, effective collection is carried out after the cooling liquid evaporates.

The condensing tubes 121 can also be placed in groups with a unit number of the condensing tubes 121 placed in each group, and then cooled collectively in groups, so that targeted heat dissipation can be carried out during subsequent heat dissipation through the air cooling structure 122.

In one implementation, in the embodiments of the present disclosure, the condensing tube 121 may be a metal flat tube; or, a capillary structure is provided in the condensing tube 121. It can be understood that the condensing chamber of the condensing tube 121 has a hollow structure, where the hollow structure includes a flattened and hollow shape or a capillary structure.

In one example, the condensing chamber of each condensing tube 121 can be used to collect vaporized cooling liquid and condense the vaporized cooling liquid from a gaseous state to a liquid state. In order to accelerate a reflux of the condensed cooling liquid to the sealing part 14, when the condensing tube 121 is a metal flat tube, a sectional area of the flat tube will be much larger than that of a cylindrical tube, and based on a thermal conductivity of the metal, when the condensing tube 121 is a metal flat tube, by increasing the heat dissipation area of the condensing tube 121 and the thermal conductivity of the metal, a conversion of the cooling liquid from gas to liquid can be accelerated, two-phase circulation is achieved; the metal flat tube can be made through aluminum extrusion, casting, and other processing methods.

Alternatively, in order to accelerate the reflux of the condensed cooling liquid to the sealing part 14, a capillary structure can be provided inside the condensing tube 121 to reduce the adhesion of the condensed cooling liquid to an inner wall of the condensing tube 121 and allow it to flow back to the sealing part 14 along the capillary structure. The capillary structure can be formed by processing the inside of the condensing tube 121, which includes at least one groove provided on the inner wall of the condensing tube 121. For example, the shape of the groove on the inner wall of the condensing tube 121 can be a spiral upward shape along the inner wall. Based on the capillary structure, the ability of the cooling liquid to return to the condensing tube 121 can be improved.

In one implementation, in the embodiments of the present disclosure, an outer wall of the condensing tube 121 is provided with multiple fins.

In one example, the outer wall of the condensing tube 121 being provided with multiple fins 1211, includes at least two implementation methods, namely, making multiple fins on the outer wall of the condensing tube 121 by mechanical processing, or distributing multiple fins on an outer surface of the condensing tube 121 by fixing methods such as fitting, welding, or pasting. Due to the installation of multiple fins, the heat dissipation area of the condensing tube 121 is increased. Therefore, the condensing tube 121 can accelerate the two-phase circulation of the cooling liquid when condensing gaseous cooling liquid, thereby improving the heat dissipation efficiency of the circuit board 20 during operation.

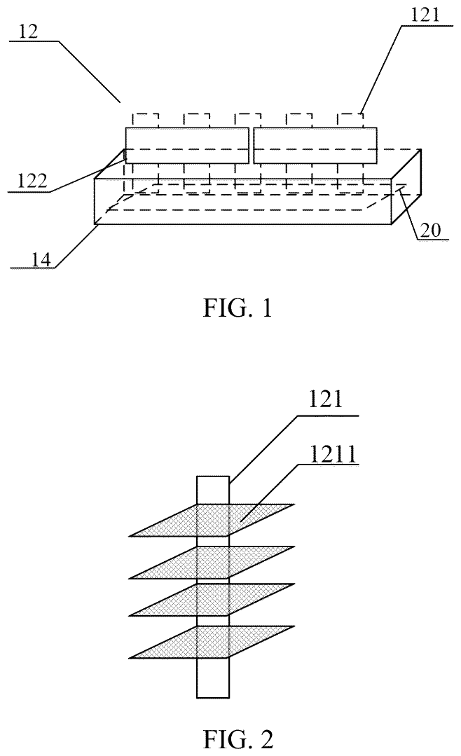

FIG. 2 shows a schematic diagram of fins of a condensing tube in a cooling apparatus provided by an example embodiment. As shown in FIG. 2, in the embodiments of the present disclosure, the outer wall of the condensing tube 121 is provided with multiple fins, where the respective fins are arranged in parallel, and from bottom to top from the lower of the condensing tube 121. It should be noted that FIG. 2 only shows the structure of one condensing tube 121, and in the embodiments of the present disclosure, the structure of each condensing tube may be the same.

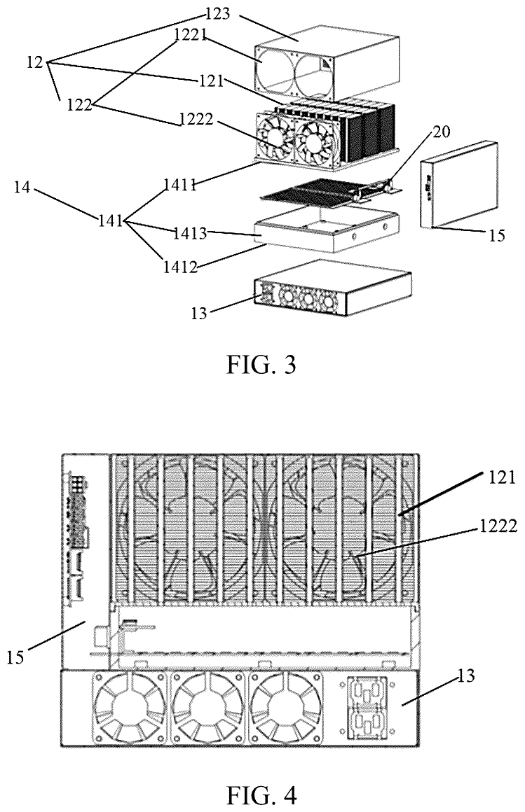

In some possible embodiments, a cooling apparatus provided by the embodiments of the present disclosure is shown in FIG. 3. FIG. 3 shows a schematic exploded diagram of a cooling apparatus provided by an example embodiment.

In the embodiments of the present disclosure, the condensing part 12 further includes a first shell 123, and a first accommodating chamber is formed by being surrounded by the first shell 123, and the condensing tube 121 is accommodated in the first accommodating chamber.

As shown in FIG. 3, the space formed by the first shell 123 of the condensing part 12 can be referred to as the first accommodating chamber. The condensing tube 121 and the air cooling structure 122 are both provided on the first shell, and the condensing tube 121 is provided in the first accommodating chamber.

It should be noted that the implementations of the embodiments of the present disclosure in the heat dissipation and cooling process of the condensing tube 121 include at least the following three modes.

Mode 1: heat dissipation by natural wind.

In one implementation, the air cooling structure 122 includes a heat dissipation hole 1221, the heat dissipation hole 1221 is provided on the side wall of the first shell 123.

As shown in FIG. 3, the heat dissipation hole 1221 is located on the side wall of the first shell 123, used to introduce external air (or cold air introduced by external devices) into the first accommodating chamber, achieving dissipating heat from the condensing tube 121 by natural wind.

In the embodiments of the present disclosure, the first shell 123 further includes a heat dissipation air channel, where the heat dissipation air channel is accommodated in the first accommodating chamber, and the heat dissipation air channel is distributed according to a position of the condensing tube 121, and is connected with the heat dissipation hole 1221.

Without adding any forced air cooling device, a heat dissipation air channel is provided inside the first shell 123, so that the heat dissipation air channel located in the first accommodating chamber can guide the air introduced from the heat dissipation hole 1221 into the position of each condensing tube 121 in a targeting manner according to the position of each condensing tube 121, achieving effective heat dissipation of the surface of the condensing tube 121 by natural wind.

Mode 2: heat dissipation by heat dissipation fan.

In one implementation, the air cooling structure 122 includes a heat dissipation fan 1222. The heat dissipation fan 1222 is installed on at least one side of the condensing tube 121.

In one example, as shown in FIG. 3, the connection structure between the heat dissipation fan 1222 and other components of the condensing part 12 is as follows: the heat dissipation fan 1222 is located on one side of the condensing tube 121, and the number of the heat dissipation holes 1221 is set according to the number of the heat dissipation fans 1222. Flowing air generated by an operation of the heat dissipation fan 1222 can dissipate heat from the condensing tube 121, improving the condensation efficiency of the cooling liquid, and accelerating the two-phase circulation of the cooling liquid.

In the embodiments of the present disclosure, the number of the heat dissipation fans 1222 is not limited, and the number of the heat dissipation fans 1222 can be increased or decreased according to the heat dissipation requirements; alternatively, in the presence of multiple heat dissipation fans, the number of the heat dissipation fans that can be turned on (or turned off) is adjusted according to control signals based on the monitored operating temperature of the PCBA, in order to meet the real-time cooling needs of the PCBA. The embodiments of the present disclosure is only illustrated by using the above example, which is subject to the cooling apparatus provided for implementing the embodiments of the present disclosure, and is not limited in detail.

In addition, it should be noted that in the implementation of the embodiments of the present disclosure, the setting mode of the heat dissipation fan 1222 also includes: without the first shell 123, the heat dissipation fan 1222 is set on one side of the condensing tube 121, and neither the condensing tube 121 nor the heat dissipation fan 1222 is wrapped by any shells. During the operation of the heat dissipation fan 1222, the condensing tube 121 is in direct contact with the outside air, increasing the heat dissipation space, improving the condensation efficiency of the cooling liquid, and accelerating the two-phase circulation of the cooling liquid.

In one example, based on the connection structure between the heat dissipation fan 1222 and the condensing tube 121, the heat dissipation fan 1222 cools the condensing tube 121 and fins. The gaseous cooling liquid liquefies again and flows back to the sealing part 14 under the action of gravity, achieving phase change cooling by the cooling apparatus provided in the embodiments of the present disclosure.

When the air cooling structure 122 includes the heat dissipation fan 1222, the cooling apparatus provided in the embodiments of the present disclosure further includes: a first power supply 13, the first power supply 13 is connected with the heat dissipation fan 1222.

When the air cooling structure 122 includes the heat dissipation fan 1222, the cooling apparatus provided in the embodiments of the present disclosure further includes: a first control circuit 15, the first control circuit 15 is connected with the heat dissipation fan 1222.

In one example, the structure in which the first power supply 13 is connected with the heat dissipation fan 1222 and the first control circuit 15 is connected with the heat dissipation fan 1222 in the embodiments of the present disclosure is not shown in FIG. 3. In FIG. 3, the first power supply 13 is configured to supply power to the heat dissipation fan 1222, and the first control circuit 15 is configured to control the operation of the heat dissipation fan 1222. Controlling the operation of the heat dissipation fan 1222 may include at least one or a combination of controlling the heat dissipation fan 1222 to turn on or turn off, controlling the operating speed of the heat dissipation fan 1222, or controlling a rotation direction of fan blades of the heat dissipation fan 1222.

Mode 3: Combination of Mode 1 and Mode 2.

In the case where the first shell 123 is provided with a heat dissipation hole 1221, the heat dissipation fan 1222 is matched with the heat dissipation hole 1221, and the heat dissipation fan 1222 is connected with the heat dissipation air channel. Through the operation of the heat dissipation fan 1222, the external air is introduced into the first shell 123 in an accelerated manner. The air introduced in an accelerated manner is transmitted to each condensing tube 121 according to the setting of the heat dissipation air channel through the heat dissipation air channel, achieving an improvement in the condensation efficiency of the cooling liquid and accelerating the two-phase circulation of the cooling liquid.

In one implementation, the sealing part 14 includes a second shell 141, a second accommodating chamber is formed by being surrounded by the second shell 141, a condensing chamber of the condensing tube 121 is connected with the second accommodating chamber.

As shown in FIG. 3, the significance of connecting the condensing chamber of the condensing tube 121 with the second accommodating chamber is that the cooling liquid in the gaseous state in the condensing tube 121 forms liquid cooling liquid after condensation. Through the structure of connecting the condensing tube 121 with the second accommodating chamber, the liquid cooling liquid in the condensing chamber of the condensing tube 121 can flow back to the second accommodating chamber, achieving two-phase circulation of the cooling liquid.

The second shell 141 includes: a cover plate 1411, a bottom plate 1412, and a side plate 1413; the cover plate 1411 is provided with a through hole, and the condensing tube 121 is provided at the through hole; the cover plate 1411, the bottom plate 1412, the side plate 1413, and the condensing tube 121 form a sealed space.

In one example, in the embodiments of the present disclosure, the condensing tube 121 is fixed to the cover plate 1411 by methods such as friction welding, brazing, or adhesive bonding. The sealing chamber formed by the cover plate 1411, the bottom plate 1412, and the side plate 1413 is sealed together by sealing rings, adhesives, and other sealing methods to form a sealing structure, in which the condensing tube 121 and the sealing chamber are connected internally.

In addition, the condensing tube 121 in the embodiments of the present disclosure can also be connected with the sealing chamber through the coordination of a mechanical connection and a sealing ring.

In the embodiments of the present disclosure, FIG. 4 shows a schematic sectional diagram of a cooling apparatus provided by an example embodiment. As shown in FIG. 4, the condensing tube 121, the first power supply 13, the first control circuit 15, and the heat dissipation fan 1222 are illustrated in the schematic sectional diagram of the cooling apparatus provided in the embodiments of the present disclosure. The shaded area where the condensing tube 121 overlaps with the heat dissipation fan 1222 is the fins of the condensing tube 121.

It should be noted that the cooling apparatus provided in the embodiments of the present disclosure is only illustrated with the above examples, which is subject to the cooling apparatus provided for implementing the embodiments of the present disclosure, and is not limited in detail.

The cooling apparatus provided in the embodiments of the present disclosure is designed as an integrated air and liquid independent chassis. The circuit board 20 and the heat-producing element are immersed in the cooling liquid, and the heat of the heat-producing element is carried away by boiling of the cooling liquid, thereby ensuring that the operating temperature of the heat-producing element is always within a safe range, and achieving cooling and temperature equalization of the heat-producing element. By integrating an integrated air cooling heat exchange section (condensing part 12 and sealing part 14), the phase change liquid is directly cooled, achieving short cooling distance and high heat exchange efficiency. An integrated design is flexibly applied, which is suitable for independent transportation and operation, cluster application can directly replace current air cooling products to adapt to various deployment forms of air cooling application scenarios. Compared to liquid cooling products, this integrated design eliminates the need for pumps and pipelines, and makes the overall design more compact and convenient.

In addition, compared to the widely used air cooling and water cooling methods, the cooling apparatus provided in the embodiments of the present disclosure utilizes phase change heat transfer to effectively reduce the operating temperature of the heat-producing element, improving temperature uniformity, and reducing system energy consumption. The efficient cooling of phase change heat transfer reduces a volume of the air cooling, and the integrated design eliminates the complex components of the water cooling. Moreover, by adopting the condensing tube structure provided in the embodiments of the present disclosure, it is possible to achieve heat dissipation for high-power systems, with a simple processing method and lower cost compared to VC, gravity heat pipes, etc.

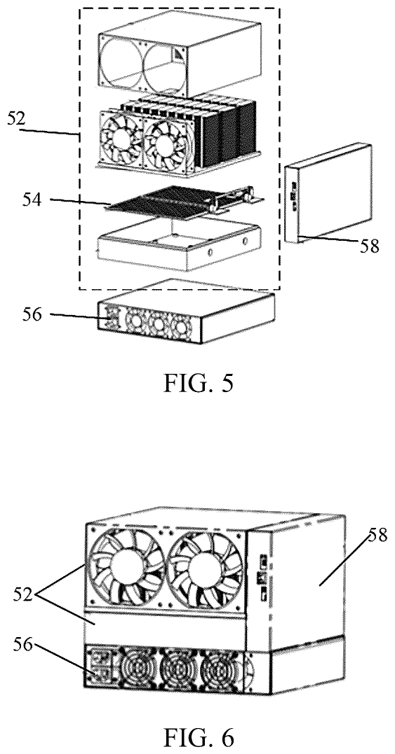

The embodiments of the present disclosure provide an electronic device as shown in FIG. 5. FIG. 5 shows a schematic diagram of an electronic device provided by an example embodiment.

The embodiments of the present disclosure provide an electronic device, which includes: the cooling apparatus 52 and the circuit board 54 as mentioned in the above embodiments, where the circuit board 54 is immersed in the cooling liquid in the sealing part, a first surface of the circuit board 54 faces toward a liquid surface of the cooling liquid, a number of heat-producing elements provided on the first surface is greater than a number of heat-producing elements provided on a second surface of the circuit board 54, and the first surface is opposite to the second surface.

The electronic device provided in the embodiments of the present disclosure can be a computing device with high computing power and high chip energy consumption, such as a server, a server cluster, or a computer. For the structure of the cooling apparatus 52, reference can be made to the description of the cooling apparatus in the above embodiments, and details will not be repeated here.

In the embodiments of the present disclosure, the first surface of the circuit board 54 may be the TOP surface of the circuit board 54, and the second surface may be the BOT surface of the circuit board 54. The TOP surface is equivalent to a front surface of the circuit board, while the BOT surface is equivalent to a back surface of the circuit board. The TOP surface and the BOT surface are matched ones, and the difference between the two is that there are more components (i.e., the heat-producing elements in the embodiments of the present disclosure) on the TOP surface, while there are fewer components on the BOT surface. Therefore, the TOP surface is set upwards, so that this surface can be completely immersed in the cooling liquid, and during the two-phase circulation of the cooling liquid, the heat from the heat-producing elements on the TOP surface is carried away acceleratively, achieving a purpose of heat dissipation for circuit board 54.

In one example, the circuit board 54 is completely immersed in the cooling liquid. When the temperature of the heat-producing element (such as the chip) exceeds the boiling point of the cooling liquid during the operation of the electronic device, the cooling liquid is caused to boil locally in vicinity of the chip, so as to carry away the heat of the chip through surface liquid vaporization. After the device runs stably, the system reaches heat transfer equilibrium, and the heat generated by the chip is continuously carried away through phase change, ensuring the stability of the chip's operating temperature.

It should be noted that in the embodiments of the present disclosure, a material of the PCBA (i.e. circuit board 54) may be FR-4 grade material, aluminum based material, copper based material, etc., and the embodiments of the present disclosure does not impose specific limitations on this. In addition, the surface of the chip may be a non-thermal expansion surface, or can be in the form of increased thermal expansion surface through soldering, adhesive bonding, deposition, etc., which is subject to the electronic device provided for implementing the embodiments of the present disclosure, and is not limited in detail.

In the embodiments of the present disclosure, an angle between the circuit board 54 and the liquid surface of the cooling liquid is a preset angle.

In one example, the angle between the circuit board 54 and the liquid surface of the cooling liquid being set to a preset angle is for that: a high-power heat-producing element can effectively contact the cooling liquid according to tilted position relationship, so that the cooling liquid can more effectively take away the heat emitted by the heat-producing element during the vaporization process, maintaining the normal operating state of the heat-producing element.

In one implementation, the electronic device provided in the embodiments of the present disclosure further includes a second power supply 56, which is connected with the circuit board 54.

In one example, as shown in FIG. 5, the second power supply 56 is connected with the circuit board 54 through a copper strip. The copper strip passes through a hole provided in the sealing part of the cooling apparatus 52, and the hole is sealed with sealant around the copper strip, thereby supplying power to the circuit board 54 through the second power supply 56.

It should be noted that in the cooling apparatus 52, the first power supply and the second power supply 56 can be the same power supply, or two power modules that supply power to the circuit board and the heat dissipation fan separately in the same power supply.

In the embodiments of the present disclosure, the control circuit in the electronic device includes two implementations.

Mode 1: the second control circuit 58 is connected with the circuit board 54 and the second power supply 56 respectively.

In one implementation, the electronic device provided in the embodiments of the present disclosure further includes a second control circuit 58, which is connected with the circuit board 54 and the second power supply 56, respectively.

In one example, in the embodiments of the present disclosure, the second control circuit 58 is connected with the circuit board 54 and the second power supply 56, respectively, and is configured to monitor and control the circuit board 54, as well as obtain power from the second power supply 56. The second control circuit 58 in the embodiments of the present disclosure can be the first control circuit in the above embodiments, or the first control circuit and the second control circuit are at two different control units on the same integrated control board.

In the embodiments of the present disclosure, FIG. 6 shows a schematic diagram of an appearance of an electronic device provided by an example embodiment. As shown in FIG. 6, the electronic device is composed of the cooling apparatus, the second power supply 56, and the second control circuit 58. The circuit board is installed in the sealing part of the cooling apparatus, the second power supply 56 is provided below the cooling apparatus, and the second control circuit 58 is located on a right side of the cooling apparatus. The embodiments of the present disclosure is only illustrated by using the above example, which is subject to the electronic device provided for implementing the embodiments of the present disclosure, and is not limited in detail.

In addition, the installation position of the second power supply 56 can also be located above the machine, on both sides, which is subject to the electronic device provided for implementing the embodiments of the present disclosure, and is not limited in detail.

In one implementation, a third control circuit is connected with the circuit board 54.

In the above scheme, the electronic device provided in the embodiments of the present disclosure further includes a third control circuit, which is connected with the circuit board 54.

The third control circuit is connected with the circuit board 54 and is configured to control the operation of the circuit board 54 or forward external instructions to the circuit board 54 through the third control circuit.

It should be noted that in the embodiments of the present disclosure, the second control circuit 58 and the third control circuit can be the same control circuit, or two different control units on the same integrated control board. Both the second control circuit 58 and the third control circuit can be connected with the circuit board 54 through an aviation plug. The aviation plug is also fixed on an outer wall of the sealing part of the cooling apparatus with sealant.

In the embodiments of the present disclosure, the electronic device provided by the embodiments of the present disclosure accommodates the cooling liquid that can be used to cool the circuit board during operation in a sealing part of the cooling apparatus. After the cooling liquid vaporizes, the cooling liquid is converted from a gaseous state to a liquid state through the condensing part and flows back to the sealing part, achieving heat dissipation of the circuit board in operation through a liquid cooling mode plus an air cooling mode. By using phase change heat transfer, the chip operating temperature can be effectively reduced, temperature uniformity can be improved, and system energy consumption can be reduced. The volume of the air cooling is reduced, and integrated design eliminates the complex components of the water cooling.

Those skilled in the art can understand that the functions described in conjunction with the various illustrative logical blocks, modules, and algorithm steps disclosed in the present disclosure can be implemented in hardware, software, firmware, or any combination thereof. If implemented in software, the functions described by various illustrative logical blocks, modules, and steps can be stored or transmitted as one or more instructions or codes on a computer-readable medium and executed by a hardware based processing unit. Computer readable media may include computer readable storage media, corresponding to tangible media such as data storage media, or communication media that includes any medium that facilitates the transfer of computer programs from one location to another (e.g., according to a communication protocol). In this way, computer-readable media can generally correspond to (1) non-temporary tangible computer-readable storage media, or (2) communication media such as signals or carriers. The data storage media may be any available medium that can be accessed by one or more computers or one or more processors to retrieve instructions, codes, and/or data structures used to implement the techniques described in the embodiments of the present disclosure. Computer program products may include computer-readable media.

The technology disclosed in the embodiments of the present disclosure can be implemented in various devices or equipment, including wireless handheld devices, integrated circuits (ICs), or a set of ICs (e.g. chipsets). The various components, modules, or units described in the embodiments of the present disclosure is intended to emphasize the functional aspects of the device for executing the disclosed technology, but may not necessarily require implementation by different hardware units. In fact, as described above, various units can be combined with appropriate software and/or firmware in the encoder decoder hardware unit, or provided through interoperable hardware units (including one or more processors as described above).

In the above embodiments, the description of each embodiment has its own emphasis. For the parts that are not detailed in one embodiment, please refer to the relevant descriptions of other embodiments.

The above is only an example specific implementation of the present disclosure, but the protection scope of the present disclosure is not limited to this. Any changes or replacements that can be easily thought of by those skilled in the art within the technical scope disclosed in the present disclosure should be included in the protection scope of the present disclosure.

1. A cooling apparatus, comprising: a condensing part and a sealing part, wherein,
the sealing part can accommodate a cooling liquid, and a circuit board mounted with a heat-producing element can be immersed in the cooling liquid; and
the condensing part comprises a condensing tube and an air cooling structure used for dissipating heat of the condensing tube, the condensing tube is connected with the sealing part, and the air cooling structure is provided on at least one side of the condensing tube.

2. The cooling apparatus according to claim 1, wherein the condensing tube is a metal flat tube; or, a capillary structure is provided in the condensing tube.

3. The cooling apparatus according to claim 1, wherein an outer wall of the condensing tube is provided with multiple fins.

4-16. (canceled)

17. The cooling apparatus according to claim 2, wherein an outer wall of the condensing tube is provided with multiple fins.

18. The cooling apparatus according to claim 1, wherein the condensing part further comprises a first shell, a first accommodating chamber is formed by being surrounded by the first shell, and the condensing tube is accommodated in the first accommodating chamber.

19. The cooling apparatus according to claim 18, wherein the air cooling structure comprises a heat dissipation hole, the heat dissipation hole is provided on a side wall of the first shell.

20. The cooling apparatus according to claim 18, wherein the first shell further comprises a heat dissipation air channel, wherein the heat dissipation air channel is accommodated in the first accommodating chamber, and the heat dissipation air channel is distributed according to a position of the condensing tube and is connected with the heat dissipation hole.

21. The cooling apparatus according to claim 1, wherein the air cooling structure comprises a heat dissipation fan.

22. The cooling apparatus according to claim 18, wherein the air cooling structure comprises a heat dissipation fan.

23. The cooling apparatus according to claim 21, wherein when the air cooling structure comprises the heat dissipation fan, the cooling apparatus further comprises: a first power supply, the first power supply is connected with the heat dissipation fan.

24. The cooling apparatus according to claim 22, wherein when the air cooling structure comprises the heat dissipation fan, the cooling apparatus further comprises: a first power supply, the first power supply is connected with the heat dissipation fan.

25. The cooling apparatus according to claim 21, wherein when the air cooling structure comprises the heat dissipation fan, the cooling apparatus further comprises: a first control circuit, the first control circuit is connected with the heat dissipation fan.

26. The cooling apparatus according to claim 22, wherein when the air cooling structure comprises the heat dissipation fan, the cooling apparatus further comprises: a first control circuit, the first control circuit is connected with the heat dissipation fan.

27. The cooling apparatus according to claim 1, wherein the sealing part comprises a second shell, a second accommodating chamber is formed by being surrounded by the second shell, a condensing chamber of the condensing tube is connected with the second accommodating chamber.

28. The cooling apparatus according to claim 27, wherein the second shell comprises: a cover plate, a bottom plate, and a side plate; wherein, the cover plate is provided with a through hole, and the condensing tube is provided at the through hole; the cover plate, the bottom plate, the side plate, and the condensing tube form a sealed space.

29. An electronic device, comprising:
the cooling apparatus and the circuit board according to claim 1, wherein the circuit board is immersed in the cooling liquid in the sealing part, a first surface of the circuit board faces toward a liquid surface of the cooling liquid, a number of heat-producing elements provided on the first surface is greater than a number of heat-producing elements provided on a second surface of the circuit board, and the first surface is opposite to the second surface.

30. The electronic device according to claim 29, wherein an angle between the circuit board and the liquid surface of the cooling liquid is a preset angle.

31. The electronic device according to claim 29, wherein the electronic device further comprises a second power supply, which is connected with the circuit board.

32. The electronic device according to claim 31, wherein the electronic device further comprises a second control circuit, which is connected with the circuit board and the second power supply, respectively.

33. The electronic device according to claim 29, wherein the electronic device further comprises a third control circuit, which is connected with the circuit board.
